(19) United States
(12) Patent Application Publication
(10) Pub. No.: US 2019/0058043 A1
(43) Pub. Date: Feb. 21, 2019

(54) TRANSISTOR GATE-CHANNEL ARRANGEMENTS

(71) Applicant: Intel Corporation, Santa Clara, CA (US)

(72) Inventors: Gilbert W. Dewey, Beaverton, OR (US); Rafael Rios, Austin, TX (US); Shriram Shivaraman, Hillsboro, OR (US); Marko Radosavljevic, Portland, OR (US); Kent E. Millard, Hillsboro, OR (US); Marc C. French, Forest Grove, OR (US); Van H. Le, Beaverton, OR (US)

(73) Assignee: Intel Corporation, Santa Clara, CA (US)

(21) Appl. No.: 16/080,101

(22) PCT Filed: Mar. 30, 2016
(86) PCT No.: PCT/US2016/024828

§ 371 Date: Aug. 27, 2018

(51) Int. Cl. H01L 29/40; H01L 29/221; H01L 29/423; H01L 29/417; H01L 29/66; H01L 29/78

(52) U.S. Cl. CPC H01L 29/408; H01L 29/221; H01L 29/42364; H01L 2029/7858; H01L 29/66795; H01L 29/785; H01L 29/41791

(57) ABSTRACT

Disclosed herein are transistor gate-channel arrangements, and related methods and devices. For example, in some embodiments, a transistor gate-channel arrangement may include a channel material and a transistor gate stack. The transistor gate stack may include a gate electrode material, a high-k dielectric disposed between the gate electrode material and the channel material, and indium gallium zinc oxide (IGZO) disposed between the high-k dielectric material and the channel material.

### BACKGROUND

Thin-film transistors may include a gate oxide between a gate electrode and a semiconducting channel. The gate oxide may be, for example, a high-k dielectric material.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a cross-sectional side view of a transistor gate-channel arrangement including a transistor gate stack, in accordance with various embodiments.

FIGS. 2-6 are cross-sectional side views of example single-gate transistors including a transistor gate stack, in accordance with various embodiments.

FIGS. 7-9 are cross-sectional side views of example double-gate transistors including a transistor gate stack, in accordance with various embodiments.

FIGS. 10A and 10B are perspective and cross-sectional side views, respectively, of an example tri-gate transistor including a transistor gate stack, in accordance with various embodiments.

FIGS. 11A and 11B are perspective and cross-sectional side views, respectively, of an example all-around gate transistor including a transistor gate stack, in accordance with various embodiments.

FIG. 12 is a flow diagram of an example method of manufacturing a transistor gate stack, in accordance with various embodiments.

FIGS. 13A and 13B are top views of a wafer and dies that include one or more transistor gate stacks in accordance with any of the embodiments disclosed herein.

FIG. 14 is a cross-sectional side view of an integrated circuit (IC) device that may include one or more transistor gate stacks in accordance with any of the embodiments disclosed herein.

FIG. 15 is a cross-sectional side view of an IC device assembly that may include one or more transistor gate stacks in accordance with any of the embodiments disclosed herein.

FIG. 16 is a block diagram of an example computing device that may include one or more transistor gate stacks in accordance with any of the embodiments disclosed herein.

### DETAILED DESCRIPTION

Disclosed herein are transistor gate-channel arrangements, and related methods and devices. For example, in some embodiments, transistor gate-channel arrangement may include a channel material and a transistor gate stack. The transistor gate stack may include a gate electrode material, a high-k dielectric disposed between the gate electrode material and the channel material, and indium gallium zinc oxide (IGZO) disposed between the high-k dielectric material and the channel material.

The performance of a thin-film transistor (TFT) may depend on the number of factors. For example, the efficiency at which a TFT is able to operate may depend on the sub threshold swing of the TFT, characterizing the amount of change in the gate-source voltage needed to achieve a given change in the drain current. A smaller sub threshold swing enables the TFT to turn off to a lower leakage value when the gate-source voltage drops below the threshold voltage of the TFT. The conventional theoretical lower limit at room temperature for the sub threshold swing of the TFT is 60 millivolts per decade of change in the drain current. The performance of a TFT may also depend on the carrier mobility of the components in the TFT. A material with a higher carrier mobility enables carriers to move more quickly in response to a given electric field than a material with a lower carrier mobility; thus, high carrier mobilities may be associated with improved performance.

The transistor gate stacks disclosed herein include a multilayer gate oxide having both a high-k dielectric and a layer of IGZO acting as the interface between the high-k dielectric and a channel material (or, in some embodiments, acting as the channel material itself). Although IGZO has a relatively low mobility (approximately 10 cm²/V-s), the sub threshold swing of IGZO may be close to the conventional theoretical lower limit. In some embodiments, a thin layer of IGZO may directly border a channel material of choice, and may be sandwiched between the channel material and the high-k dielectric.

The use of IGZO at the interface between the gate stack and the channel may achieve one or more of a number of advantages. An IGZO interface may have a relatively small number of interface traps, defects at which carriers are trapped and released that impede performance. A gate stack that includes an IGZO interface may exhibit desirably low gate leakage. When IGZO is used as an interface to a non-IGZO semiconducting oxide channel material (e.g., a thin film oxide semiconductor material having a higher mobility than IGZO), the benefits of the higher mobility channel material may be realized simultaneously with the good gate oxide interface properties provided by the IGZO. Indeed, the gate-channel arrangements disclosed herein enable the use of a wider array of thin film transistor channel materials, while achieving desirable gate control, than realizable using conventional approaches.

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges.

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. As used herein, a “high-k dielectric” refers to a material having a higher dielectric constant than silicon oxide.

FIG. 1 is a cross-sectional side view of a transistor gate-channel arrangement 101 including a channel material 102 and a transistor gate stack 100 (also referred to as a “gate stack 100” herein), in accordance with various embodiments. The transistor gate stack 100 may include a gate electrode material 108, and a multilayer gate oxide 110 disposed between the gate electrode material 108 and the channel material 102.

The channel material 102 may be composed of semiconductor material systems including, for example, N-type or P-type materials systems. In some embodiments, the channel material 102 may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In particular, in some embodiments, a channel material 102 having a higher carrier mobility than IGZO may be used. In some embodiments, the channel material 102 may be IGZO; examples of such embodiments are discussed in further detail below. Although embodiments in which the channel material 102 is IGZO may have lower carrier mobility than embodiments in which the channel material 102 is a high mobility semiconductor material, the use of an IGZO channel may achieve performance requirements in certain applications and may be simpler to manufacture. The use of IGZO 104 as the gate oxide interface, along with the use of a channel material 102 having a higher carrier mobility than IGZO, may enable a transistor including the gate-channel arrangement 101 to take advantage of the high quality interface properties of IGZO and the high mobility of the channel material 102. The channel material 102 may have a thickness 113. In some embodiments, the thickness 113 may be between 5 and 30 nanometers.

The gate electrode material 108 may include at least one P-type work function metal or N-type work function metal, depending on whether the transistor gate stack 100 is to be included in a P-type metal oxide semiconductor (PMOS) transistor or an N-type metal oxide semiconductor (NMOS) transistor. For a PMOS transistor, metals that may be used for the gate electrode material 108 may include, but are not limited to, ruthenium, palladium, platinum, cobalt, nickel, and conductive metal oxides (e.g., ruthenium oxide). For an NMOS transistor, metals that may be used for the gate electrode material 108 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode material 108 may consist of a stack of two or more metal layers, where one or more metal layers are work function metal layers and at least one metal layer is a fill metal layer. Further metal layers may be included for other purposes, such as to act as a barrier layer.

The multilayer gate oxide 110 may include a high-k dielectric 106 and IGZO 104, arranged in the gate stack 100 so that the IGZO 104 is disposed between the high-k dielectric 106 and the channel material 102. The IGZO 104 may be in contact with the channel material 102, and may provide the interface between the channel material 102 and the remainder of the multilayer gate oxide 110. The IGZO 104 may have a gallium to indium ratio of 1:1, a gallium to indium ratio greater than 1 (e.g., 2:1, 3:1, 4:1, 5:1, 6:1, 7:1, 8:1, 9:1, or 10:1), and/or a gallium to indium ratio less than 1 (e.g., 1:2, 1:3, 1:4, 1:5, 1:6, 1:7, 1:8, 1:9, or 1:10). As used herein, “low indium content” IGZO may refer to IGZO having more gallium than indium (e.g., with a gallium to indium ratio greater than 1:1), and may also be referred to as “high gallium content” IGZO. Similarly, “low gallium content” IGZO may refer to IGZO having more indium than gallium (e.g., with a gallium to indium ratio less than 1:1), and may also be referred to as “high indium content” IGZO.

In some embodiments, the IGZO 104 may be in contact with the high-k dielectric 106, while in other embodiments, an intermediate material may be disposed between the IGZO 104 and the high-k dielectric 106. In some embodiments, the IGZO 104 may include multiple regions of IGZO having different material properties. For example, the IGZO 104 may include low indium content IGZO close to (e.g., in contact with) the high-k dielectric 106, and a high indium content IGZO close to (e.g., in contact with) the channel material 102. High indium content IGZO may provide higher mobility and poorer interface properties relative to low indium content IGZO, while low indium content IGZO may provide a wider band gap, lower gate leakage, and better interface properties, although a lower mobility, relative to high indium content IGZO.

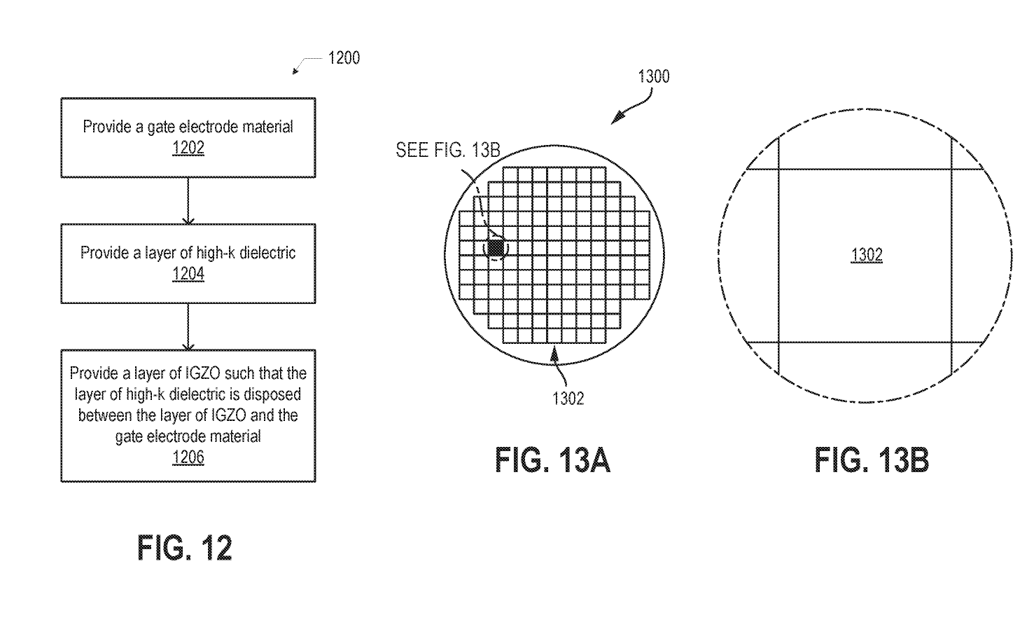

The IGZO 104 may be an amorphous, crystalline, or semi crystalline oxide semiconductor and, as discussed below with reference to FIG. 12, may be formed using a low-temperature deposition process, such as physical vapor deposition (PVD) (e.g., sputtering), atomic layer deposition (ALD), or chemical vapor deposition (CVD). The ability to deposit the IGZO 104 at temperatures low enough to be compatible with back-end manufacturing processes represents a particular advantage. The IGZO 104 may be deposited on sidewalls or conformably on any desired structure to a precise thickness, allowing the manufacture of transistors having any desired geometry. Additionally, deposition of the IGZO 104 may be compatible with deposition of many materials that may act as the high-k dielectric 106 (e.g., hafnium oxide). The IGZO 104 may have a thickness 112. In some embodiments, the thickness 112 may be between 0.5 nanometers and 5 nanometers (e.g., between 5 Angstroms and 3 nanometers, or between 6 Angstroms and 3 nanometers). When the IGZO 104 borders a channel material 102 different from IGZO, the thickness 112 of the IGZO 104 may be selected to be low enough to limit spillover of carriers, as determined by the application. As noted above, in some embodiments, the channel material 102 may itself be IGZO; in such embodiments, a single layer or region of IGZO may act as both the IGZO 104 and the channel material 102.

The high-k dielectric 106 may include elements such as hafnium, silicon, oxygen, titanium, tantalum, lanthanum, aluminum, zirconium, barium, strontium, yttrium, lead, scandium, niobium, and zinc. Examples of high-k materials that may be used in the high-k dielectric 106 may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, an annealing process may be carried out on the high-k dielectric 106 during manufacture of the gate stack 100 to improve the quality of the high-k dielectric 106. The high-k dielectric 106 may have a thickness 114. In some embodiments, the thickness 114 may be between 0.5 nanometers and 3 nanometers (e.g., between 1 and 3 nanometers, or between 1 and 2 nanometers).

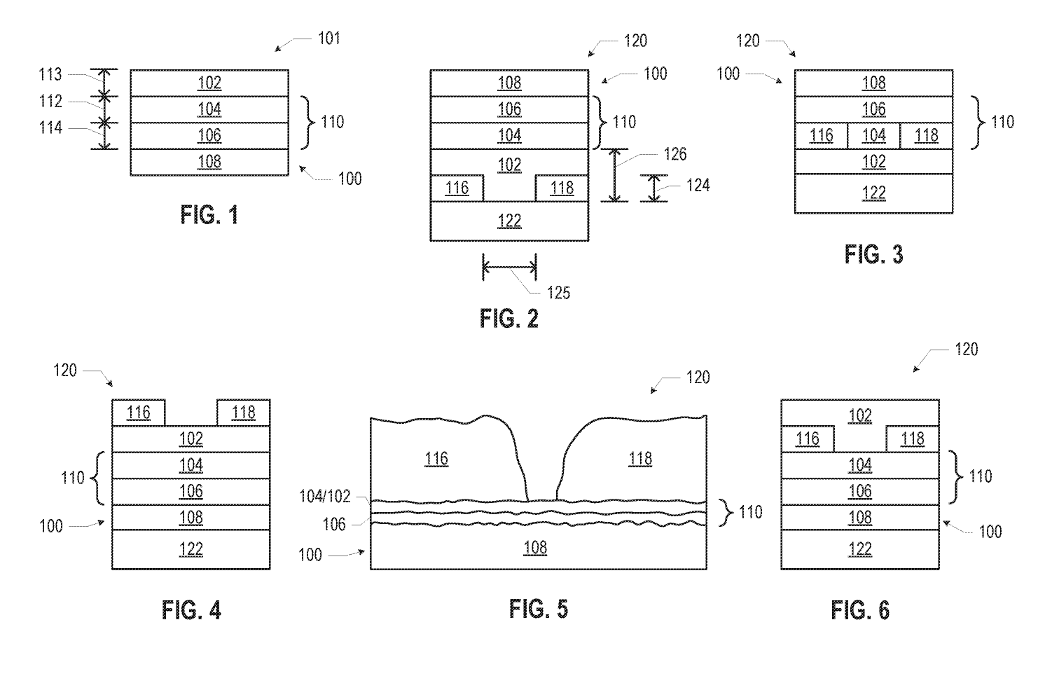

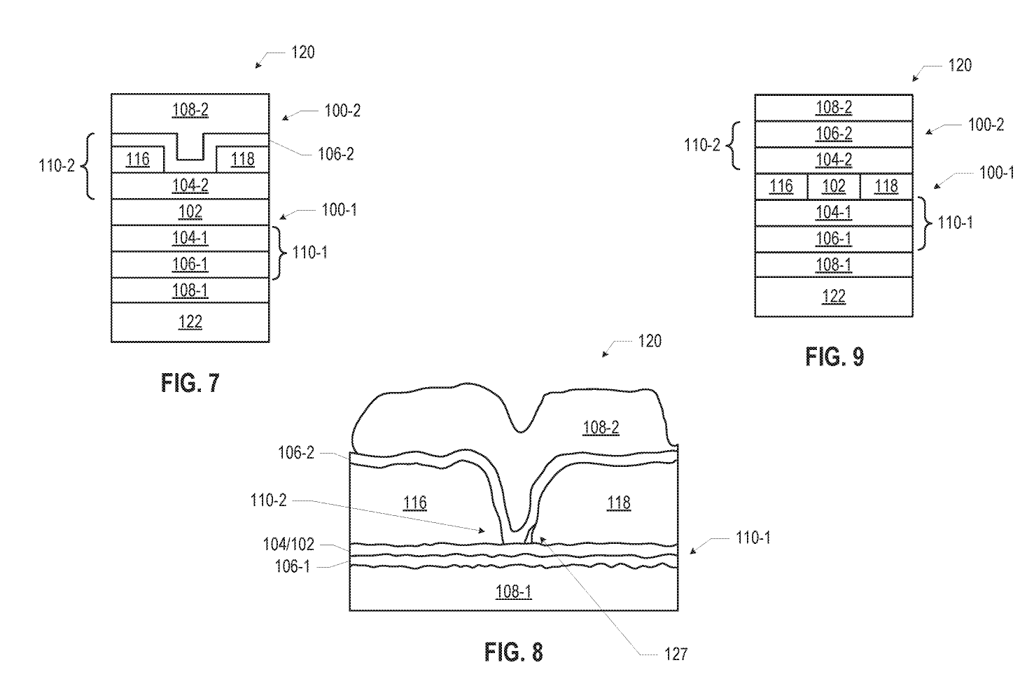

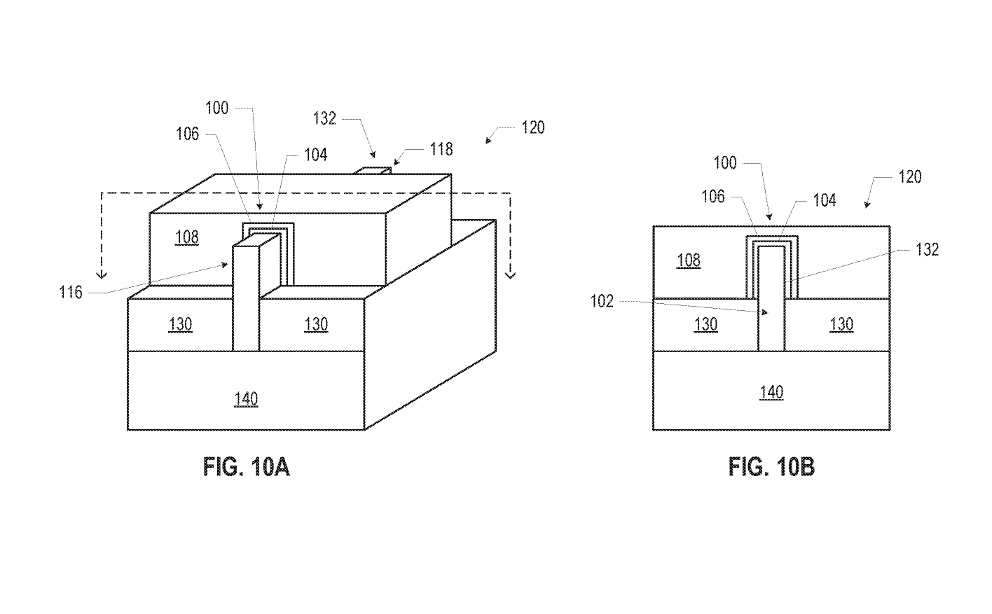

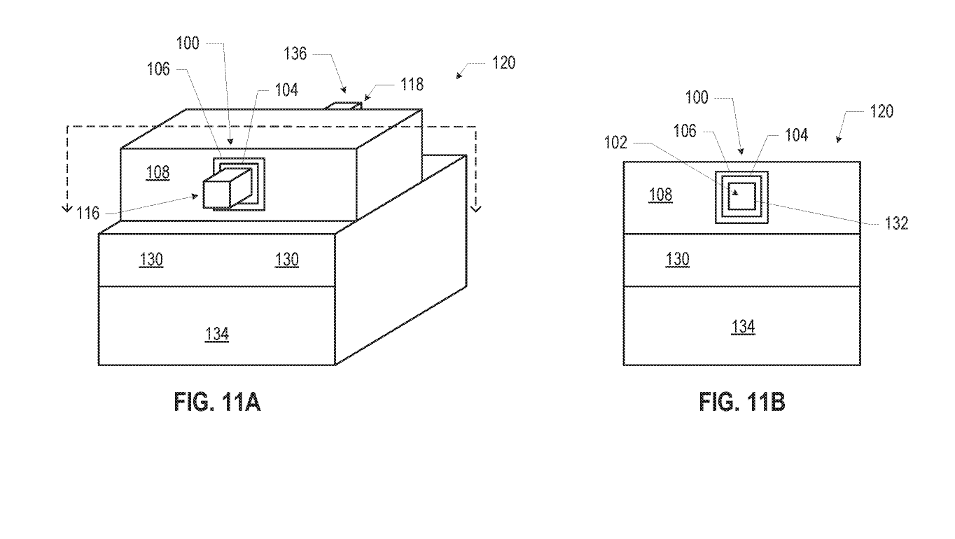

The transistor gate stack 100 may be included in any suitable transistor structure. For example, FIGS. 2-6 are cross-sectional side views of example single-gate transistors 120 including a transistor gate stack 100, FIGS. 7-9 are cross-sectional side views of example double-gate transistors 120 including a transistor gate stack 100, FIGS. 10A and 10B are perspective and cross-sectional side views, respectively, of an example tri-gate transistor 120 including a transistor gate stack, and FIGS. 11A and 11B are perspective and cross-sectional side views, respectively, of an example all-around gate transistor 120 including a transistor gate stack, in accordance with various embodiments. The transistors 120 illustrated in FIGS. 2-11 do not represent an exhaustive set of transistor structures in which a gate stack 100 may be included, but that may provide examples of such structures. Although particular arrangements of materials are discussed below with reference to FIGS. 2-11, intermediate materials may be included in the gate stacks 100 of the transistors 120 as discussed above with reference to FIG. 1. Note that FIGS. 2-6 are intended to show relative arrangements of the components therein, and that transistors 120 may include other components that are not illustrated (e.g., electrical contacts to the source region 116 and the drain region 118 to transport current in and out of the transistors 120). Any of the components of the transistors 120 discussed below with reference to FIGS. 2-11 may take the form of any of the embodiments of those components discussed above with reference to FIG. 1. Additionally, although various components of the transistors 120 are illustrated in FIGS. 2-11 as being planar rectangles or formed of rectangular solids, this is simply for ease of illustration, and embodiments of these transistors 120 may be curved, rounded, or otherwise irregularly shaped as dictated by the manufacturing processes used to fabricate the transistors 120.

FIG. 2 depicts a transistor 120 including a transistor gate stack 100 and having a single “top” gate provided by the gate electrode material 108 and the multilayer gate oxide 110 (which includes the high-k dielectric 106 and the IGZO 104). The multilayer gate oxide 110 may be disposed between the gate electrode material 108 and the channel material 102. The multilayer gate oxide 110 may border the channel material 102; in particular, the IGZO 104 may contact the channel material 102 without any intervening material (and in some embodiments, the IGZO 104 may be the channel material 102). In the embodiment of FIG. 2, the gate stack 100 is shown as disposed on a substrate 122. The substrate 122 may be any structure on which the gate stack 100, or other elements of the transistor 120, is disposed. In some embodiments, the substrate 122 may include a semiconductor, such as silicon. In some embodiments, the substrate 122 may include an insulating layer, such as an oxide isolation layer. For example, in the embodiments of FIGS. 2 and 3, the substrate 122 may include a semiconductor material and an interface layer dielectric (ILD) disposed between the semiconductor material and the source region 116, the channel material 102, and the drain region 118, to electrically isolate the semiconductor material of the substrate 122 from the source region 116, the channel material 102, and the drain region 118 (and thereby mitigate the likelihood that a conductive pathway will form between the source region 116 and the drain region 118 through the substrate 122). Examples of ILDs that may be included in a substrate 122 in some embodiments may include silicon oxide, silicon nitride, aluminum oxide, and/or silicon oxynitride. Any suitable ones of the embodiments of the substrate 122 described with reference to FIG. 2 may be used for the substrates 122 of others of the transistors 102 disclosed herein.

As noted above, the transistor 120 may include a source region 116 and a drain region 118 disposed on the substrate 122, with the channel material 102 disposed between the source region 116 and the drain region 118 so that at least some of the channel material 102 is coplanar with at least some of the source region 116 and the drain region 118. The source region 116 and the drain region 118 may have a thickness 124, and the channel material 102 may have a thickness 126. The thickness 126 may take the form of any of the embodiments of the thickness 113 discussed above with reference to FIG. 1. In some embodiments, the thickness 124 may be less than the thickness 126 (as illustrated in FIG. 2, with the source region 116 and the drain region 118 each disposed between some of the channel material 102 and the substrate 122), while in other embodiments, the thickness 124 may be equal to the thickness 126. In some embodiments, the channel material 102, the IGZO 104, the high-k dielectric 106, and/or the gate electrode material 108 may conform around the source region 116 and/or the drain region 118. The source region 116 and the drain region 118 may be spaced apart by a distance 125 that is the gate length of the transistor 120. In some embodiments, the gate length may be between 20 and 30 nanometers (e.g., between 22 and 28 nanometers, or approximately 25 nanometers).

The source region 116 and the drain region 118 may be formed using any suitable processes known in the art. For example, one or more layers of metal and/or metal alloys may be deposited or otherwise provided to form the source region 116 and the drain region 118, as known for thin film transistors based on semiconductor oxide systems. Any suitable ones of the embodiments of the source region 116 and the drain region 118 described above may be used for any of the source regions 116 and drain regions 118 described herein.

FIG. 3 depicts a transistor 120 including a transistor gate stack 100 and having a single “top” gate provided by the gate electrode material 108 and the multilayer gate oxide 110 (which includes the high-k dielectric 106 and the IGZO 104). The multilayer gate oxide 110 may be disposed between the gate electrode material 108 and the channel material 102. The multilayer gate oxide 110 may border the channel material 102; in particular, the IGZO 104 may contact the channel material 102 without any intervening material (and in some embodiments, the IGZO 104 may be the channel material 102). In the embodiment of FIG. 3, the gate stack 100 is shown as disposed on a substrate 122. The transistor 120 may include a source region 116 and a drain region 118 disposed on the substrate 122, with the IGZO 104 disposed between the source region 116 and the drain region 118 so that at least some of the IGZO 104 is coplanar with at least some of the source region 116 and the drain region 118. As discussed above, in some embodiments, the substrate 122 of FIG. 3 may include a semiconductor material and ILD disposed between the semiconductor material and the source region 116, the channel material 102, and the drain region 118, to electrically isolate the semiconductor material of the substrate 122 from the source region 116, the channel material 102, and the drain region 118. In some embodiments, the IGZO 104, the high-k dielectric 106, and/or the gate electrode material 108 may conform around the source region 116 and/or the drain region 118.

FIG. 4 depicts a transistor 120 including a transistor gate stack 100 and having a single “bottom” gate provided by the gate electrode material 108 and the multilayer gate oxide 110 (which includes the high-k dielectric 106 and the IGZO 104). The multilayer gate oxide 110 may be disposed between the gate electrode material 108 and the channel material 102. The multilayer gate oxide 110 may border the channel material 102; in particular, the IGZO 104 may contact the channel material 102 without any intervening material (and in some embodiments, the IGZO 104 may be the channel material 102). In the embodiment of FIG. 4, the gate stack 100 is shown as disposed on a substrate 122 in an orientation “upside down” to the one illustrated in FIG. 2; that is, the gate electrode material 108 may be disposed between the substrate 122 and the channel material 102. The transistor 120 may include a source region 116 and a drain region 118 disposed on the channel material 102 such that the source region 116 and the drain region 118 are not coplanar with the channel material 102.

FIG. 5 depicts a transistor 120 having the structure of the transistor 120 of FIG. 4. In particular, the transistor 120 of FIG. 5 includes a transistor gate stack 100 and has a single “bottom” gate provided by the gate electrode material 108 and the multilayer gate oxide 110 (which includes the high-k dielectric 106 and the IGZO 104). In the embodiment of FIG. 5, the IGZO 104 provides the channel material 102, so the channel material 102 is not separately labeled. The transistor 120 of FIG. 5 may also include a substrate 122 (not shown) arranged so that the gate electrode material 108 is disposed between the substrate 122 and the multilayer gate oxide 110. The transistor 120 may include a source region 116 and a drain region 118 disposed on the channel 102 such that the source region 116 and the drain region 118 are not coplanar with the channel material 102. In the embodiment depicted in FIG. 5, the source region 116 and the drain region 118 may be deposited on the IGZO 104. Any suitable materials may be used to form the transistor 120 of FIG. 5, as discussed above. For example, the gate electrode material 108 may be titanium nitride, the high-k dielectric 106 may be hafnium oxide, and the source region 116 and the drain region 118 may be formed of aluminum. The gate length of the transistor 120 of FIG. 5 may be approximately 25 nanometers.

FIG. 6 depicts a transistor 120 including a transistor gate stack 100 and having a single “bottom” gate provided by the gate electrode material 108 and the multilayer gate oxide 110 (which includes the high-k dielectric 106 and the IGZO 104). The multilayer gate oxide 110 may be disposed between the gate electrode material 108 and the channel material 102. The multilayer gate oxide 110 may border the channel material 102; in particular, the IGZO 104 may contact the channel material 102 without any intervening material (and in some embodiments, the IGZO 104 may be the channel material 102). In the embodiment of FIG. 6, the gate stack 100 is shown as disposed on a substrate 122 in an orientation “upside down” to the one illustrated in FIG. 2; that is, the gate electrode material 108 may be disposed between the substrate 122 and the channel material 102. The transistor 120 may include a source region 116 and a drain region 118 disposed on the channel material 102 such that at least some of the source region 116 and at least some of the drain region 118 are coplanar with at least some of the channel material 102. In some embodiments, the source region 116 and the drain region 118 may each be disposed between some of the channel material 102 and the substrate 122, as illustrated in FIG. 6, while in other embodiments, the channel material 102 may not extend “above” the source region 116 or the drain region 118. In some embodiments, the channel material 102 may conform around the source region 116 and/or the drain region 118.

FIG. 7 depicts a double-gate transistor 120 including two transistor gate stacks 100-1 and 100-2 and having “bottom” and “top” gates provided by the gate electrode material 108-1/multilayer gate oxide 110-1 and the gate electrode material 108-2/multilayer gate oxide 110-2, respectively. The multilayer gate oxides 110-1 and 110-2 may include a high-k dielectric 106-1 and 106-2, and IGZO 104-1 and 104-2, respectively. Each multilayer gate oxide 110 may be disposed between the corresponding gate electrode material 108 and the channel material 102. Each multilayer gate oxide 110 may border the channel material 102; in particular, the IGZO 104-1 and 104-2 may contact the channel material 102 without any intervening material (and in some embodiments, the IGZO 104-1/104-2 may be the channel material 102). The transistor 120 may include a source region 116 and a drain region 118 disposed proximate to the channel material 102. In the embodiment illustrated in FIG. 7, the source region 116 and the drain region 118 are disposed on the IGZO 104-2, and the high-k dielectric 106-2 is disposed conformably around the source region 116, the IGZO 104-2, and the drain region 118. The gate electrode material 108-2 is disposed on the high-k dielectric 106-2. In the embodiment of FIG. 7, at least some of the source region 116 and at least some of the drain region 118 are coplanar with at least some of the high-k dielectric 106-2.

FIG. 8 depicts a double-gate transistor 120 having the structure of the transistor 120 of FIG. 7. In particular, the transistor 120 of FIG. 8 includes two transistor gate stacks 100-1 and 100-2 and having “bottom” and “top” gates provided by the gate electrode material 108-1/multilayer gate oxide 110-1 and the gate electrode material 108-2/multilayer gate oxide 110-2, respectively. In the embodiment of FIG. 8, a continuous region of IGZO provides the IGZO 104-1, the channel material 102, and the IGZO 104-2. The transistor 120 of FIG. 8 may also include a substrate 122 (not shown) arranged so that the gate electrode material 108-1 is disposed between the substrate 122 and the multilayer gate oxide 110. The transistor 120 may include a source region 116 and a drain region 118 disposed on the channel material 102 such that the source region 116 and the drain region 118 are not coplanar with the channel material 102. In the embodiment depicted in FIG. 8, the source region 116 and the drain region 118 may be deposited on the IGZO 104. During manufacture, a void 127 may be formed between the high-k dielectric 106-2 and the IGZO 104; while such voids 127 may reduce the performance of the transistor 120, the transistor 120 may still function adequately as long as adequate coupling between the high-k dielectric 106-2 and the IGZO 104 is achieved. Any suitable materials may be used to form the transistor 120 of FIG. 8, as discussed above. For example, the gate electrode material 108-1 may be titanium nitride, the high-k dielectrics 106-1 and 106-2 may be hafnium oxide, the source region 116 and the drain region 118 may be formed of aluminum, and the gate electrode material 108-2 may be palladium. The gate length of the transistor 120 of FIG. 8 may be approximately 25 nanometers.

FIG. 9 depicts a double-gate transistor 120 including two transistor gate stacks 100-1 and 100-2 and having “bottom” and “top” gates provided by the gate electrode material 108-1/multilayer gate oxide 110-1 and the gate electrode material 108-2/multilayer gate oxide 110-2, respectively. Each multilayer gate oxide 110 may include a high-k dielectric 106 and IGZO 104. Each multilayer gate oxide 110 may be disposed between the corresponding gate electrode material 108 and the channel material 102. Each multilayer gate oxide 110 may border the channel material 102; in particular, the IGZO 104-1 and 104-2 may contact the channel material 102 without any intervening material (and in some embodiments, the IGZO 104-1/104-2 may be the channel material 102). The transistor 120 may include a source region 116 and a drain region 118 disposed proximate to the channel material 102. In the embodiment illustrated in FIG. 9, the source region 116 and the drain region 118 are coplanar with the channel material 102, and disposed between the high-k dielectrics 106-1 and 106-2. The relative arrangement of the source region 116, the drain region 118, and the channel material 102 may take the form of any of the embodiments discussed above with reference to FIG. 2.

FIGS. 10A and 10B are perspective and cross-sectional side views, respectively, of an example tri-gate transistor 120 including a transistor gate stack 100, in accordance with various embodiments. The transistor 120 of FIGS. 10A and 10B may include a channel material 102, and a gate stack 100 including a gate electrode material 108, a high-k dielectric 106 and IGZO 104. The IGZO 104 may be disposed between the high-k dielectric 106 and the channel material 102 (e.g., IGZO 104 may be in contact with the channel material 102). In the tri-gate transistor 120 illustrated in FIGS. 10A and 10B, a fin 132 formed of a semiconductor material may extend from a base 140 of the semiconductor material. An oxide material 130 may be disposed on either side of the fin 132. In some embodiments, the oxide material 130 may include any of the materials discussed herein with reference to the high-k dielectric 106.

The gate stack 100 may wrap around the fin 132 as shown, with the channel material 102 corresponding to the portion of the fin 132 wrapped by the gate stack 100. In particular, the IGZO 104 may wrap around the channel material 102 of the fin 132, the high-k dielectric 106 may wrap around the IGZO 104, and the gate electrode material 108 may wrap around the high-k dielectric 106. The fin 132 may include a source region 116 and a drain region 118 on either side of the gate stack 100, as shown. The composition of the channel material 102, the source region 116, and a drain region 118 may take the form of any of the embodiments disclosed herein, or known in the art. Although the fin 132 illustrated in FIGS. 10A and 10B is shown as having a rectangular cross section, the fin 132 may instead have a cross section that is rounded or sloped at the “top” of the fin 132, and the gate stack 100 may conform to this rounded or sloped fin 132. In use, the tri-gate transistor 120 may form conducting channels on three “sides” of the fin 132, potentially improving performance relative to single-gate transistors (which may form conducting channels on one “side” of the channel material 102) and double-gate transistors (which may form conducting channels on two “sides” of the channel material 102).

FIGS. 11A and 11B are perspective and cross-sectional side views, respectively, of an example all-around gate transistor 120 including a transistor gate stack 100, in accordance with various embodiments. The transistor 120 of FIGS. 11A and 11B may include a channel material 102, and a gate stack 100 including a gate electrode material 108, a high-k dielectric 106 and IGZO 104. The IGZO 104 may be disposed between the high-k dielectric 106 and the channel material 102 (e.g., IGZO 104 may be in contact with the channel material 102). In the all-around gate transistor 120 illustrated in FIGS. 11A and 11B, a wire 136 formed of a semiconductor material may extend above a substrate 134 and a layer of oxide material 130. The wire 136 may take the form of a nanowire or nanoribbon, for example. The gate stack 100 may wrap entirely or almost entirely around the wire 136, as shown, with the channel material 102 corresponding to the portion of the wire 136 wrapped by the gate stack 100. In particular, the IGZO 104 may wrap around the channel material 102 of the fin 132, the high-k dielectric 106 may wrap around the IGZO 104, and the gate electrode material 108 may wrap around the high-k dielectric 106. In some embodiments, the gate stack 100 may fully encircle the wire 136. The wire 136 may include a source region 116 and a drain region 118 on either side of the gate stack 100, as shown. The composition of the channel material 102, the source region 116, and a drain region 118 may take the form of any of the embodiments disclosed herein, or known in the art. Although the wire 136 illustrated in FIGS. 11A and 11B is shown as having a rectangular cross section, the wire 136 may instead have a cross section that is rounded or otherwise irregularly shaped, and the gate stack 100 may conform to the shape of the wire 136. In use, the tri-gate transistor 120 may form conducting channels on more than three “sides” of the wire 136, potentially improving performance relative to tri-gate transistors. Although FIGS. 11A and 11B depict an embodiment in which the longitudinal axis of the wire 136 runs substantially parallel to a plane of the oxide material 130 (and a plane of the substrate 134), this need not be the case; in other embodiments, for example, the wire 136 may be oriented “vertically” so as to be perpendicular to a plane of the oxide 130 (or plane of the substrate 134).

The transistor gate stacks 100 disclosed herein may be manufactured using any suitable techniques. For example, FIG. 12 is a flow diagram of an example method 1200 of manufacturing a transistor gate stack, in accordance with various embodiments. Although the operations of the method 1200 are illustrated once each and in a particular order, the operations may be performed in any suitable order and repeated as desired. For example, one or more operations may be performed in parallel to manufacture multiple transistor gate stacks substantially simultaneously. In another example, the operations may be performed in a different order to reflect the structure of a transistor in which the transistor gate stack will be included (e.g., the gate electrode material of the transistor 120 of FIG. 5 may be provided before the IGZO 104, while the gate electrode material of the transistor 120 of FIG. 10 may be provided after the IGZO 104).

At 1202, a gate electrode material may be provided. The gate electrode material provided at 1202 may take the form of any of the embodiments of the gate electrode material 108 disclosed herein, for example (e.g., any of the embodiments discussed herein with reference to a transistor 120). The gate electrode material may be provided at 1202 using any suitable deposition and patterning technique known in the art.

At 1204, a layer of high-k dielectric may be provided. The high-k dielectric provided at 1204 may take the form of any of the embodiments of the high-k dielectric 106 disclosed herein, for example. In some embodiments, the layer of high-k dielectric may be provided at 1204 so as to be in contact with the gate electrode material of 1202. In other embodiments, an intermediate material may be disposed between the gate electrode material and the layer of high-k dielectric. The high-k dielectric may be provided at 1204 using any suitable technique known in the art.

At 1206, a layer of IGZO may be provided such that the layer of high-k dielectric is disposed between the layer of IGZO and the gate electrode material. The IGZO provided at 1206 may take the form of any of the embodiments of the IGZO 104 disclosed herein. In some embodiments, the IGZO provided at 1206 may be in contact with a channel material of a transistor (e.g., the channel material 102 of any of the transistors 120 disclosed herein). The IGZO may be provided at 1206 using any suitable technique known in the art. For example, in some embodiments, the layer of IGZO may be provided by physical vapor deposition (PVD), such as sputtering. In some embodiments, the layer of IGZO may be provided by atomic layer deposition (ALD). In some embodiments, the layer of IGZO may be provided by chemical vapor deposition (CVD).

The method 1200 may further include other manufacturing operations related to fabrication of other components of a transistor 120. For example, the method 1200 may include providing a channel material different from the IGZO provided at 1206 (e.g., in accordance with any suitable ones of the embodiments discussed above). In some embodiments, the method 1200 may include providing a source region and a drain region (e.g., in accordance with any suitable ones of the embodiments discussed above).

The transistor gate stacks disclosed herein may be included in any suitable electronic device. FIGS. 13-16 illustrate various examples of apparatuses that may include one or more of the transistor gate stacks disclosed herein.

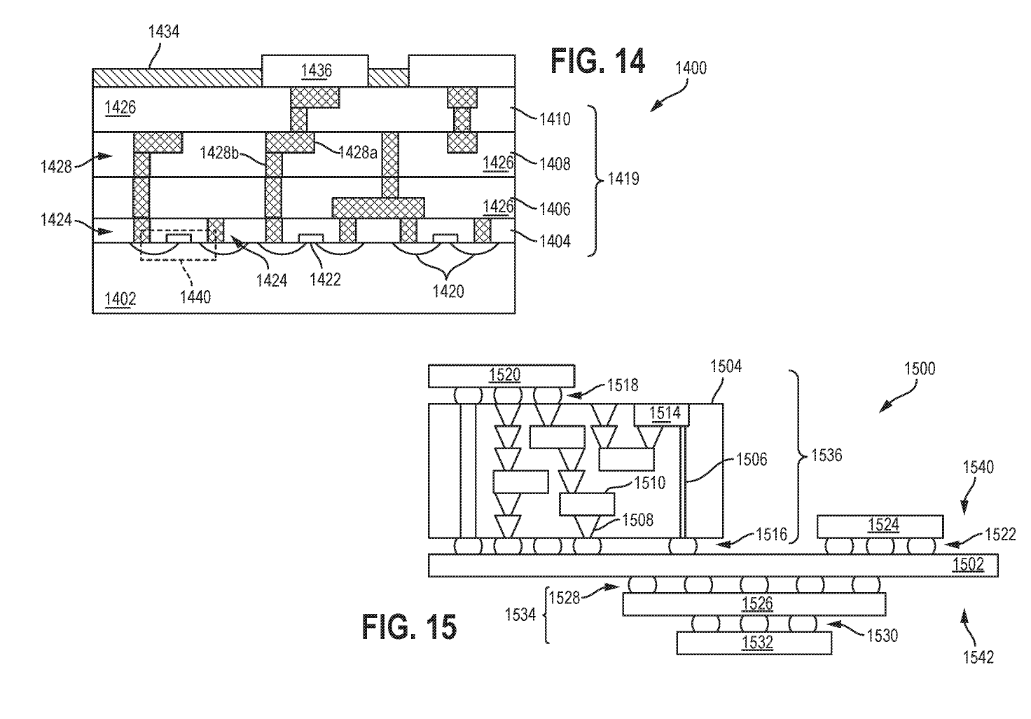

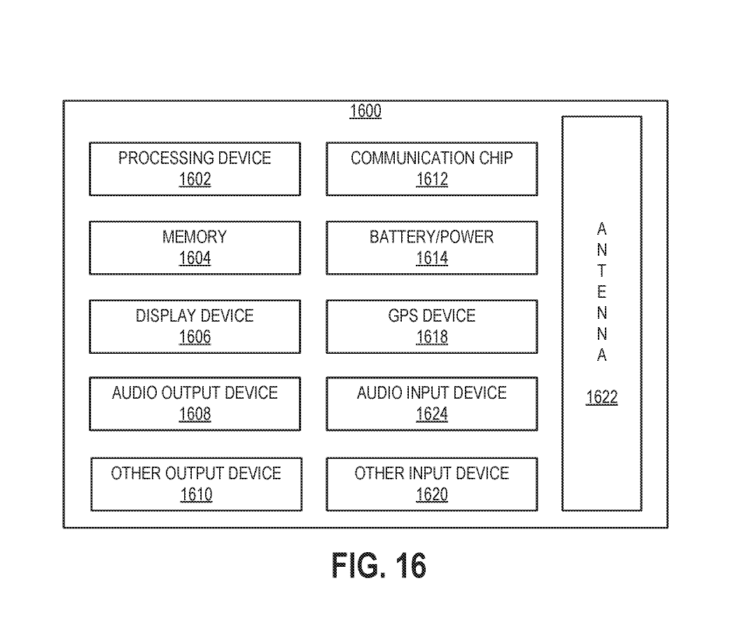

FIGS. 13A-B are top views of a wafer 1300 and dies 1302 that may include one or more transistor gate stacks in accordance with any of the embodiments disclosed herein. The wafer 1300 may be composed of semiconductor material and may include one or more dies 1302 having IC structures formed on a surface of the wafer 1300. Each of the dies 1302 may be a repeating unit of a semiconductor product that includes any suitable IC (e.g., ICs including one or more transistors 120 that include one or more gate stacks 100). After the fabrication of the semiconductor product is complete (e.g., after manufacture of a gate stack 100 in a transistor 120), the wafer 1300 may undergo a singulation process in which each of the dies 1302 is separated from one another to provide discrete “chips” of the semiconductor product. In particular, devices that include a transistor gate stack as disclosed herein may take the form of the wafer 1300 (e.g., not singulated) or the form of the die 1302 (e.g., singulated). The die 1302 may include one or more transistors (e.g., one or more of the transistors 1440 of FIG. 14, discussed below, which may take the form of any of the transistors 120) and/or supporting circuitry to route electrical signals to the transistors, as well as any other IC components. In some embodiments, the wafer 1300 or the die 1302 may include a memory device (e.g., a static random access memory (SRAM) device), a logic device (e.g., an AND, OR, NAND, or NOR gate), or any other suitable circuit element. Multiple ones of these devices may be combined on a single die 1302. For example, a memory array formed by multiple memory devices may be formed on a same die 1302 as a processing device (e.g., the processing device 1602 of FIG. 16) or other logic that is configured to store information in the memory devices or execute instructions stored in the memory array.

FIG. 14 is a cross-sectional side view of an IC device 1400 that may include one or more transistor gate stacks in accordance with any of the embodiments disclosed herein. The IC device 1400 may be formed on a substrate 1402 (e.g., the wafer 1300 of FIG. 13A) and may be included in a die (e.g., the die 1302 of FIG. 13B). The substrate 1402 may be a semiconductor substrate composed of semiconductor material systems including, for example, N-type or P-type materials systems. The substrate 1402 may include, for example, a crystalline substrate formed using a bulk silicon or a silicon-on-insulator substructure. In some embodiments, the semiconductor substrate 1402 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the substrate 1402. Although a few examples of materials from which the substrate 1402 may be formed are described here, any material that may serve as a foundation for an IC device 1400 may be used. The substrate 1402 may be part of a singulated die (e.g., the dies 1302 of FIG. 13B) or a wafer (e.g., the wafer 1300 of FIG. 13A).

The IC device 1400 may include one or more device layers 1404 disposed on the substrate 1402. The device layer 1404 may include features of one or more transistors 1440 (e.g., metal oxide semiconductor field-effect transistors (MOSFETs)) formed on the substrate 1402. The device layer 1404 may include, for example, one or more source and/or drain (S/D) regions 1420, a gate 1422 to control current flow in the transistors 1440 between the S/D regions 1420, and one or more S/D contacts 1424 to route electrical signals to/from the S/D regions 1420. The transistors 1440 may include additional features not depicted for the sake of clarity, such as device isolation regions, gate contacts, and the like. The transistors 1440 are not limited to the type and configuration depicted in FIG. 14 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors. In particular, one or more of the transistors 1440 may include one or more transistor gate stacks 100 in accordance with any of the embodiments disclosed herein. For example, a transistor 1440 may take the form of any of the transistors 120 disclosed herein (e.g., any of the single-gate transistors discussed herein with reference to FIGS. 2-6, any of the double-gate transistors discussed herein with reference to FIGS. 7-9, any of the tri-gate transistors discussed herein with reference to FIGS. 10A and 10B, and any of the all-around-gate transistors discussed herein with reference to FIGS. 11A and 11B). The S/D regions 1420 may include the source region 116 and the drain region 118. Thin-film transistors 120 including the gate stack 100 may be particularly advantageous when used in the metal layers of a microprocessor device for analog circuitry, logic circuitry, or memory circuitry, and may be formed along with existing complementary metal oxide semiconductor (CMOS) processes.

Each transistor 1440 may include a gate 1422 formed of at least two layers, a gate dielectric layer and a gate electrode layer. The gate electrode layer may take the form of any of the embodiments of the gate electrode material 108 disclosed herein. In embodiments in which a transistor 1440 includes one or more transistor gate stacks 100, the gate dielectric layer may take the form of any of the embodiments of the multilayer gate oxide 110 disclosed herein, and may include IGZO 104 and a high-k dielectric 106. Generally, the gate dielectric layer of a transistor 1440 may include one layer or a stack of layers, and the one or more layers may include silicon oxide, silicon dioxide, and/or a high-k dielectric material. The high-k dielectric material included in the gate dielectric layer of the transistor 1440 may take the form of any of the embodiments of the high-k dielectric 106 disclosed herein, for example.

In some embodiments, when viewed as a cross section of the transistor 1440 along the source-channel-drain direction, the gate electrode may consist of a U-shaped structure that includes a bottom portion substantially parallel to the surface of the substrate and two sidewall portions that are substantially perpendicular to the top surface of the substrate (e.g., as discussed above with reference to the tri-gate transistor 120 of FIGS. 10A and 10B). In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may consist of a combination of U-shaped structures and planar, non-U-shaped structures. For example, the gate electrode may consist of one or more U-shaped metal layers formed atop one or more planar, non-U-shaped layers. In some embodiments, the gate electrode may consist of a V-shaped structure (e.g., when the fin 132 does not have a “flat” upper surface, but instead has a rounded peak).

In some embodiments, a pair of sidewall spacers may be formed on opposing sides of the gate stack to bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1420 may be formed within the substrate 1402 adjacent to the gate 1422 of each transistor 1440. The S/D regions 1420 may take the form of any of the embodiments of the source region 116 and the drain region 118 discussed above with reference to the transistors 120. In other embodiments, the S/D regions 1420 may be formed using any suitable processes known in the art. For example, the S/D regions 1420 may be formed using either an implantation/diffusion process or a deposition process. In the former process, dopants such as boron, aluminum, antimony, phosphorous, or arsenic may be ion-implanted into the substrate 1402 to form the S/D regions 1420. An annealing process that activates the dopants and causes them to diffuse farther into the substrate 1402 may follow the ion implantation process. In the latter process, an epitaxial deposition process may provide material that is used to fabricate the S/D regions 1420. In some implementations, the S/D regions 1420 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1420 may be formed using one or more alternate semiconductor materials such as germanium or a group III-V material or alloy. In further embodiments, one or more layers of metal and/or metal alloys may be used to form the S/D regions 1420 (e.g., as discussed above with reference to the source region 116 and the drain region 118). In some embodiments, an etch process may be performed before the epitaxial deposition to create recesses in the substrate 1402 in which the material for the S/D regions 1420 is deposited.

Electrical signals, such as power and/or input/output (I/O) signals, may be routed to and/or from the transistors 1440 of the device layer 1404 through one or more interconnect layers disposed on the device layer 1404 (illustrated in FIG. 14 as interconnect layers 1406-1410). For example, electrically conductive features of the device layer 1404 (e.g., the gate 1422 and the S/D contacts 1424) may be electrically coupled with the interconnect structures 1428 of the interconnect layers 1406-1410. The one or more interconnect layers 1406-1410 may form an interlayer dielectric (ILD) stack 1419 of the IC device 1400.

The interconnect structures 1428 may be arranged within the interconnect layers 1406-1410 to route electrical signals according to a wide variety of designs (in particular, the arrangement is not limited to the particular configuration of interconnect structures 1428 depicted in FIG. 14). Although a particular number of interconnect layers 1406-1410 is depicted in FIG. 14, embodiments of the present disclosure include IC devices having more or fewer interconnect layers than depicted.

In some embodiments, the interconnect structures 1428 may include trench structures 1428a (sometimes referred to as “lines”) and/or via structures 1428b (sometimes referred to as “holes”) filled with an electrically conductive material such as a metal. The trench structures 1428a may be arranged to route electrical signals in a direction of a plane that is substantially parallel with a surface of the substrate 1402 upon which the device layer 1404 is formed. For example, the trench structures 1428a may route electrical signals in a direction in and out of the page from the perspective of FIG. 14. The via structures 1428b may be arranged to route electrical signals in a direction of a plane that is substantially perpendicular to the surface of the substrate 1402 upon which the device layer 1404 is formed. In some embodiments, the via structures 1428b may electrically couple trench structures 1428a of different interconnect layers 1406-1410 together.

The interconnect layers 1406-1410 may include a dielectric material 1426 disposed between the interconnect structures 1428, as shown in FIG. 14. In some embodiments, the dielectric material 1426 disposed between the interconnect structures 1428 in different ones of the interconnect layers 1406-1410 may have different compositions; in other embodiments, the composition of the dielectric material 1426 between different interconnect layers 1406-1410 may be the same.

A first interconnect layer 1406 (referred to as Metal 1 or “M1”) may be formed directly on the device layer 1404. In some embodiments, the first interconnect layer 1406 may include trench structures 1428a and/or via structures 1428b, as shown. The trench structures 1428a of the first interconnect layer 1406 may be coupled with contacts (e.g., the S/D contacts 1424) of the device layer 1404.

A second interconnect layer 1408 (referred to as Metal 2 or “M2”) may be formed directly on the first interconnect layer 1406. In some embodiments, the second interconnect layer 1408 may include via structures 1428b to couple the trench structures 1428a of the second interconnect layer 1408 with the trench structures 1428a of the first interconnect layer 1406. Although the trench structures 1428a and the via structures 1428b are structurally delineated with a line within each interconnect layer (e.g., within the second interconnect layer 1408) for the sake of clarity, the trench structures 1428a and the via structures 1428b may be structurally and/or materially contiguous (e.g., simultaneously filled during a dual-damascene process) in some embodiments.

A third interconnect layer 1410 (referred to as Metal 3 or “M3”) (and additional interconnect layers, as desired) may be formed in succession on the second interconnect layer 1408 according to similar techniques and configurations described in connection with the second interconnect layer 1408 or the first interconnect layer 1406.

The IC device 1400 may include a solder resist material 1434 (e.g., polyimide or similar material) and one or more bond pads 1436 formed on the interconnect layers 1406-1410. The bond pads 1436 may be electrically coupled with the interconnect structures 1428 and configured to route the electrical signals of the transistor(s) 1440 to other external devices. For example, solder bonds may be formed on the one or more bond pads 1436 to mechanically and/or electrically couple a chip including the IC device 1400 with another component (e.g., a circuit board). The IC device 1400 may have other alternative configurations to route the electrical signals from the interconnect layers 1406-1410 than depicted in other embodiments. For example, the bond pads 1436 may be replaced by or may further include other analogous features (e.g., posts) that route the electrical signals to external components.

FIG. 15 is a cross-sectional side view of an IC device assembly 1500 that may include components having one or more transistor gate stacks in accordance with any of the embodiments disclosed herein. The IC device assembly 1500 includes a number of components disposed on a circuit board 1502 (which may be, e.g., a motherboard). The IC device assembly 1500 includes components disposed on a first face 1540 of the circuit board 1502 and an opposing second face 1542 of the circuit board 1502; generally, components may be disposed on one or both faces 1540 and 1542. In particular, any suitable ones of the components of the IC device assembly 1500 may include any of the transistor gate stacks 100 disclosed herein (e.g., in any of the transistors 120 disclosed herein).

In some embodiments, the circuit board 1502 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1502. In other embodiments, the circuit board 1502 may be a non-PCB substrate.

The IC device assembly 1500 illustrated in FIG. 15 includes a package-on-interposer structure 1536 coupled to the first face 1540 of the circuit board 1502 by coupling components 1516. The coupling components 1516 may electrically and mechanically couple the package-on-interposer structure 1536 to the circuit board 1502, and may include solder balls (as shown in FIG. 15), male and female portions of a socket, an adhesive, an underfill material, and/or any other suitable electrical and/or mechanical coupling structure.

The package-on-interposer structure 1536 may include an IC package 1520 coupled to an interposer 1504 by coupling components 1518. The coupling components 1518 may take any suitable form for the application, such as the forms discussed above with reference to the coupling components 1516. Although a single IC package 1520 is shown in FIG. 15, multiple IC packages may be coupled to the interposer 1504; indeed, additional interposers may be coupled to the interposer 1504. The interposer 1504 may provide an intervening substrate used to bridge the circuit board 1502 and the IC package 1520. The IC package 1520 may be or include, for example, a die (the die 1302 of FIG. 13B), an IC device (e.g., the IC device 1400 of FIG. 14), or any other suitable component. Generally, the interposer 1504 may spread a connection to a wider pitch or reroute a connection to a different connection. For example, the interposer 1504 may couple the IC package 1520 (e.g., a die) to a ball grid array (BGA) of the coupling components 1516 for coupling to the circuit board 1502. In the embodiment illustrated in FIG. 15, the IC package 1520 and the circuit board 1502 are attached to opposing sides of the interposer 1504; in other embodiments, the IC package 1520 and the circuit board 1502 may be attached to a same side of the interposer 1504. In some embodiments, three or more components may be interconnected by way of the interposer 1504.

The interposer 1504 may be formed of an epoxy resin, a fiberglass-reinforced epoxy resin, a ceramic material, or a polymer material such as polyimide. In some implementations, the interposer 1504 may be formed of alternate rigid or flexible materials that may include the same materials described above for use in a semiconductor substrate, such as silicon, germanium, and other group III-V and group IV materials. The interposer 1504 may include metal interconnects 1508 and vias 1510, including but not limited to through-silicon vias (TSVs) 1506. The interposer 1504 may further include embedded devices 1514, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio-frequency (RF) devices, power amplifiers, power management devices, antennas, arrays, sensors, and microelectromechanical systems (MEMS) devices may also be formed on the interposer 1504. The package-on-interposer structure 1536 may take the form of any of the package-on-interposer structures known in the art.

The IC device assembly 1500 may include an IC package 1524 coupled to the first face 1540 of the circuit board 1502 by coupling components 1522. The coupling components 1522 may take the form of any of the embodiments discussed above with reference to the coupling components 1516, and the IC package 1524 may take the form of any of the embodiments discussed above with reference to the IC package 1520.

The IC device assembly 1500 illustrated in FIG. 15 includes a package-on-package structure 1534 coupled to the second face 1542 of the circuit board 1502 by coupling components 1528. The package-on-package structure 1534 may include an IC package 1526 and an IC package 1532 coupled together by coupling components 1530 such that the IC package 1526 is disposed between the circuit board 1502 and the IC package 1532. The coupling components 1528 and 1530 may take the form of any of the embodiments of the coupling components 1516 discussed above, and the IC packages 1526 and 1532 may take the form of any of the embodiments of the IC package 1520 discussed above. The package-on-package structure 1534 may be configured in accordance with any of the package-on-package structures known in the art.

FIG. 16 is a block diagram of an example computing device 1600 that may include one or more components including one or more transistor gate stacks in accordance with any of the embodiments disclosed herein. For example, any suitable ones of the components of the computing device 1600 may include a die (e.g., the die 1302 (FIG. 13B)) having one or more transistors 120 including one or more transistor gate stacks 100. Any one or more of the components of the computing device 1600 may include, or be included in, an IC device 1400 (FIG. 14). Any one or more of the components of the computing device 1600 may include, or be included in, an IC device assembly 1500 (FIG. 15).

A number of components are illustrated in FIG. 16 as included in the computing device 1600, but any one or more of these components may be omitted or duplicated, as suitable for the application. In some embodiments, some or all of the components included in the computing device 1600 may be attached to one or more motherboards. In some embodiments, some or all of these components are fabricated onto a single system-on-a-chip (SoC) die.

Additionally, in various embodiments, the computing device 1600 may not include one or more of the components illustrated in FIG. 16, but the computing device 1600 may include interface circuitry for coupling to the one or more components. For example, the computing device 1600 may not include a display device 1606, but may include display device interface circuitry (e.g., a connector and driver circuitry) to which a display device 1606 may be coupled. In another set of examples, the computing device 1600 may not include an audio input device 1624 or an audio output device 1608, but may include audio input or output device interface circuitry (e.g., connectors and supporting circuitry) to which an audio input device 1624 or audio output device 1608 may be coupled.

The computing device 1600 may include a processing device 1602 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1602 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 1600 may include a memory 1604, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 1604 may include memory that shares a die with the processing device 1602. This memory may be used as cache memory and may include embedded dynamic random access memory (eDRAM) or spin transfer torque magnetic random-access memory (STT-M RAM).

In some embodiments, the computing device 1600 may include a communication chip 1612 (e.g., one or more communication chips). For example, the communication chip 1612 may be configured for managing wireless communications for the transfer of data to and from the computing device 1600. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1612 may implement any of a number of wireless standards or protocols, including but not limited to Institute for Electrical and Electronic Engineers (IEEE) standards including Wi-Fi (IEEE 1402.11 family), IEEE 1402.16 standards (e.g., IEEE 1402.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.16 standards. The communication chip 1612 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1612 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1612 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1612 may operate in accordance with other wireless protocols in other embodiments. The computing device 1600 may include an antenna 1622 to facilitate wireless communications and/or to receive other wireless communications (such as AM or FM radio transmissions).

In some embodiments, the communication chip 1612 may manage wired communications, such as electrical, optical, or any other suitable communication protocols (e.g., the Ethernet). As noted above, the communication chip 1612 may include multiple communication chips. For instance, a first communication chip 1612 may be dedicated to shorter-range wireless communications such as Wi-Fi or Bluetooth, and a second communication chip 1612 may be dedicated to longer-range wireless communications such as GPS, EDGE, GPRS, CDMA, WiMAX, LTE, EV-DO, or others. In some embodiments, a first communication chip 1612 may be dedicated to wireless communications, and a second communication chip 1612 may be dedicated to wired communications.

The computing device 1600 may include battery/power circuitry 1614. The battery/power circuitry 1614 may include one or more energy storage devices (e.g., batteries or capacitors) and/or circuitry for coupling components of the computing device 1600 to an energy source separate from the computing device 1600 (e.g., AC line power).

The computing device 1600 may include a display device 1606 (or corresponding interface circuitry, as discussed above). The display device 1606 may include any visual indicators, such as a heads-up display, a computer monitor, a projector, a touchscreen display, a liquid crystal display (LCD), a light-emitting diode display, or a flat panel display, for example.

The computing device 1600 may include an audio output device 1608 (or corresponding interface circuitry, as discussed above). The audio output device 1608 may include any device that generates an audible indicator, such as speakers, headsets, or earbuds, for example.

The computing device 1600 may include an audio input device 1624 (or corresponding interface circuitry, as discussed above). The audio input device 1624 may include any device that generates a signal representative of a sound, such as microphones, microphone arrays, or digital instruments (e.g., instruments having a musical instrument digital interface (MIDI) output).

The computing device 1600 may include a global positioning system (GPS) device 1618 (or corresponding interface circuitry, as discussed above). The GPS device 1618 may be in communication with a satellite-based system and may receive a location of the computing device 1600, as known in the art.

The computing device 1600 may include an other output device 1610 (or corresponding interface circuitry, as discussed above). Examples of the other output device 1610 may include an audio codec, a video codec, a printer, a wired or wireless transmitter for providing information to other devices, or an additional storage device.

The computing device 1600 may include an other input device 1620 (or corresponding interface circuitry, as discussed above). Examples of the other input device 1620 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 1600 may have any desired form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 1600 may be any other electronic device that processes data.

The following paragraphs provide various examples of the embodiments disclosed herein.

Example 1 is a transistor gate-channel arrangement, including: a channel material; and a transistor gate stack, including a gate electrode material, a high-k dielectric disposed between the gate electrode material and the channel material, and indium gallium zinc oxide (IGZO) disposed between the high-k dielectric material and the channel material.

Example 2 may include the subject matter of Example 1, and may further specify that the channel material is IGZO.

Example 3 may include the subject matter of any of Examples 1-2, and may further specify that the channel material includes tin oxide, antimony oxide, indium oxide, indium tin oxide, titanium oxide, zinc oxide, indium zinc oxide, gallium oxide, titanium oxynitride, ruthenium oxide, or tungsten oxide.

Example 4 may include the subject matter of any of Examples 1-3, and may further specify that the IGZO is in contact with the channel material.

Example 5 may include the subject matter of any of Examples 1-4, and may further specify that the high-k dielectric material is in contact with the gate electrode material.

Example 6 may include the subject matter of any of Examples 1-5, and may further specify that the IGZO has a thickness between 0.5 nanometers and 5 nanometers.

Example 7 may include the subject matter of any of Examples 1-6, and may further specify that the high-k dielectric has a thickness between 0.5 and 3 nanometers.

Example 8 may include the subject matter of any of Examples 1-7, and may further specify that the high-k dielectric includes hafnium oxide.

Example 9 may include the subject matter of any of Examples 1-8, and may further specify that the high-k dielectric includes zirconium oxide, aluminum oxide, tantalum oxide, tantalum silicon oxide, hafnium silicon oxide, or lanthanum oxide.

Example 10 is a transistor, including: a channel material; a gate electrode material; a multilayer gate oxide disposed between the gate electrode material and the channel material, wherein the multilayer gate oxide includes a high-k dielectric and indium gallium zinc oxide (IGZO), and the IGZO is in contact with the channel material; a source region; and a drain region.

Example 11 may include the subject matter of Example 10, and may further specify that the transistor has a gate length between 20 and 30 nanometers.

Example 12 may include the subject matter of any of Examples 10-11, and may further specify that the channel material is coplanar with the source region and the drain region.

Example 13 may include the subject matter of any of Examples 10-12, and may further include a transistor substrate, wherein the source region and the drain region are disposed between the gate electrode material on the transistor substrate.

Example 14 may include the subject matter of any of Examples 10-11, and may further include a transistor substrate, wherein the gate electrode material is disposed between the source region and the transistor substrate.

Example 15 may include the subject matter of any of Examples 10-11, and may further specify that: the gate electrode material is a first gate electrode material; the multilayer gate oxide is a first multilayer gate oxide; the transistor further comprises a second gate electrode material and a second multilayer gate oxide; the channel material is disposed between the first and second multilayer gate oxides; and the first and second multilayer gate oxides are disposed between the first and second gate electrode materials.

Example 16 may include the subject matter of Example 15, and may further specify that the channel material is coplanar with the source region and the drain region.

Example 17 may include the subject matter of any of Examples 15-16, and may further specify that the channel material is IGZO.

Example 18 may include the subject matter of any of Examples 10-11, and may further specify that the channel material is shaped as a fin, and the multilayer gate oxide wraps around the fin.

Example 19 may include the subject matter of any of Examples 10-11, and may further specify that the channel material is shaped as a wire, and the multilayer gate oxide wraps around the wire.

Example 20 may include the subject matter of Example 19, and may further specify that the multilayer gate oxide wraps entirely around the wire.

Example 21 is a computing device, including: a substrate; and an integrated circuit (IC) die coupled to the substrate, wherein the IC die includes a transistor having a channel material, a gate electrode material, a multilayer gate oxide disposed between the gate electrode material and the channel material, wherein the multilayer gate oxide includes a high-k dielectric and indium gallium zinc oxide (IGZO), and the IGZO is in contact with the channel material, a source region, and a drain region.

Example 22 may include the subject matter of Example 21, and may further specify that the computing device is a wearable or handheld computing device.

Example 23 may include the subject matter of any of Examples 21-22, and may further specify that the computing device further includes one or more communication chips and an antenna.

Example 24 may include the subject matter of any of Examples 21-23, and may further specify that the substrate is a motherboard.

Example 25 is a method of manufacturing a transistor, including: providing a gate electrode material; providing a layer of high-k dielectric; and providing a layer of indium gallium zinc oxide (IGZO) such that the layer of high-k dielectric is disposed between the layer of IGZO and the gate electrode material.

Example 26 may include the subject matter of Example 25, and may further specify that providing the layer of IGZO comprises performing atomic layer deposition, physical vapor deposition, or chemical vapor deposition of IGZO.

Example 27 may include the subject matter of any of Examples 25-26, and may further include providing a channel material different from the IGZO such that the IGZO is disposed between the channel material and the layer of high-k dielectric.

Example 28 may include the subject matter of any of Examples 25-27, and may further include providing a source region and a drain region spaced apart by a gate length between 20 and 30 nanometers.

Example 29 may include the subject matter of any of Examples 25-28, and may further specify that the layer of IGZO at least partially wraps around a channel material.

Example 30 may include the subject matter of Example 29, and may further specify that the layer of IGZO encircles the channel material.

1. A transistor gate-channel arrangement, comprising:
a channel material; and
a transistor gate stack, including:
a gate electrode material,
a high-k dielectric material disposed between the gate electrode material and the channel material, and
indium gallium zinc oxide (IGZO) disposed between the high-k dielectric material and the channel material.

2. The transistor gate-channel arrangement of claim 1, wherein the channel material is IGZO.

3. The transistor gate-channel arrangement of claim 1, wherein the channel material includes tin oxide, antimony oxide, indium oxide, indium tin oxide, titanium oxide, zinc oxide, indium zinc oxide, gallium oxide, titanium oxynitride, ruthenium oxide, or tungsten oxide.

4. The transistor gate-channel arrangement of claim 1, wherein the IGZO is in contact with the channel material.

5. The transistor gate-channel arrangement of claim 1, wherein the high-k dielectric material is in contact with the gate electrode material.

6. The transistor gate-channel arrangement of claim 1, wherein the IGZO has a thickness between 0.5 nanometers and 5 nanometers.

7. The transistor gate-channel arrangement of claim 1, wherein the high-k dielectric material has a thickness between 0.5 and 3 nanometers.

8. The transistor gate-channel arrangement of claim 1, wherein the high-k dielectric material includes hafnium oxide.

9. The transistor gate-channel arrangement of claim 1, wherein the high-k dielectric material includes zirconium oxide, aluminum oxide, tantalum oxide, tantalum silicon oxide, hafnium silicon oxide, or lanthanum oxide.

10. A transistor, comprising:
a channel material;
a gate electrode material;
a multilayer gate oxide disposed between the gate electrode material and the channel material, wherein the multilayer gate oxide includes a high-k dielectric and indium gallium zinc oxide (IGZO), and the IGZO is in contact with the channel material;
a source region; and
a drain region.

11. The transistor of claim 10, wherein the transistor has a gate length between 20 and 30 nanometers.

12. The transistor of claim 10, wherein the channel material is coplanar with the source region and the drain region.

13. The transistor of claim 10, wherein the channel material is shaped as a fin, and the multilayer gate oxide wraps around the fin.

14. The transistor of claim 10, wherein the channel material is shaped as a wire, and the multilayer gate oxide wraps around the wire.

15. The transistor of claim 14, wherein the multilayer gate oxide wraps entirely around the wire.

16. A computing device, comprising:
a substrate; and
an integrated circuit (IC) die coupled to the substrate, wherein the IC die includes a transistor having:
a channel material,
a gate electrode material,
a multilayer gate oxide disposed between the gate electrode material and the channel material, wherein the multilayer gate oxide includes a high-k dielectric and indium gallium zinc oxide (IGZO), and the IGZO is in contact with the channel material,
a source region, and
a drain region.

17. The computing device of claim 16, wherein the computing device is a wearable or handheld computing device.

18. The computing device of claim 16, wherein the computing device further includes one or more communication chips and an antenna.

19. The computing device of claim 16, wherein the substrate is a motherboard.

20. A method of manufacturing a transistor, comprising:
providing a gate electrode material;
providing a layer of high-k dielectric; and
providing a layer of indium gallium zinc oxide (IGZO) such that the layer of high-k dielectric is disposed between the layer of IGZO and the gate electrode material.

21. The method of claim 20, wherein providing the layer of IGZO comprises performing atomic layer deposition, physical vapor deposition, or chemical vapor deposition of IGZO.

22. The method of claim 20, further comprising:
providing a channel material different from the IGZO such that the IGZO is disposed between the channel material and the layer of high-k dielectric.

23. The method of claim 20, further comprising:
providing a source region and a drain region spaced apart by a gate length between 20 and 30 nanometers.

24. The method of claim 20, wherein the layer of IGZO at least partially wraps around a channel material.

25. The method of claim 24, wherein the layer of IGZO encircles the channel material.
